(19) United States
(12) Patent Application Publication
(10) Pub. No.: US 2007/0052354 A1
(43) Pub. Date: Mar. 8, 2007

(54) Organic electroluminescent display device with color

(75) Inventors: Joel Chia-Yeh Chang, Chu Nan (TW); Chih-Ming Chin, Chu Nan (TW); Sheng-Hsu Shih, Chu Nan (TW); Wen-Jeng Lang, Chu Nan (TW); Chien-Chih Chiang, Chu Nan (TW)

Correspondence Address: BIRCH STEWART KOLASCH & BIRCH, PO BOX 747, FALLS CHURCH, VA, 22040-0747, US

(73) Assignee: Univision Technology Inc.

(21) Appl. No.: 11/509,039

(22) Filed: Aug. 24, 2006

(30) Foreign Application Priority Data
Sep. 2, 2005 (TW) 94130170

(51) Int. Cl. H01J 1/62

(52) U.S. Cl. 313/509

(57) ABSTRACT

An organic electroluminescent (OEL) display device with color level enhancement is provided. The OEL display device includes a plurality of pixels on a substrate. Each of the pixels comprises a first color filter layer, a first electrode, a first OEL layer, a second OEL layer and a second electrode. The color filter layer includes a first, a second, a third and a fourth photo resist. The first OEL layer is disposed on the vertically extended position of the first, the second and the fourth photo resist. The second OEL layer is disposed on the vertically extended position of the second, the third and the fourth photo resist.

### RELATED APPLICATIONS

The present application is based on, and claims priority from, Taiwan Application Serial Number 94130170, filed Sep. 2, 2005, the disclosure of which is hereby incorporated by reference herein in its entirety.

### BACKGROUND

1. Field of Invention

The present invention relates to an organic electroluminescent (OEL) display device. More particularly, the present invention relates to an OEL display device with color level enhancement.

2. Description of Related Art

The key point of successfully developing a display device is how to achieve full-color display effect. For an OEL display device, there are two common methods to achieve full-color display effect:

1. Independent pixels of three primary colors: the OEL elements of three primary colors (red, green, and blue) are separately disposed in the OEL display device. In addition, the lights of these three colors are mixed in appropriate ratios to obtain full-color effect.

However, there are several times of evaporation and masking processes in manufacturing an OEL display device with OEL elements of different colors thereon. Thus, the manufacturing processes are very complicated. Moreover, High precision alignment for the mask and the evaporation source in the processes is required. Therefore, the product failure rate and the manufacturing cost are high.

2. Color filter: at least a white-light OEL element equipped with a color filter is disposed on an OEL display device. The color filter filters the white light generated from the OEL element to achieve full color display effect.

FIG. 1 is a cross-sectional view of an OEL display device utilizing a color filter to achieve full color effect. In FIG. 1, the color filter 10 comprises a black matrix 13 and a color filter layer 15. The black matrix 13 is disposed on a substrate 11. The color filter layer 15 is disposed on the black matrix 13 and the substrate 11 where no black matrix 13 is formed thereon. The color filter layer 15 comprises at least a first photo resist 151 (green), a second photo resist 153 (blue) and a third photo resist 155 (red).

A planarization barrier element 17 can be optionally formed on the black matrix 13 and the color filter layer 15 to facilitate following processes proceeding. The planarization barrier element 17 can be an over coat layer or a barrier layer.

Moreover, a first electrode 21 of the OEL device 20 is disposed directly on the planarization barrier element 17. An OEL layer 23 and a second electrode 25 are sequentially disposed on the first electrode 21. A white light source S is generated from the OEL layer 23 when a working current is conducted between the first electrode 21 and the second electrode 25. The white light source S is filtered by the color filter layer 15 and converted to a first color light L1 (green), a second color light L2 (blue) and a third color light L3 (red). The first color light L1, the second color light L2 and the third color light L3 are mixed in different ratios to achieve full color display of the OEL display device.

By using the color filter 10, the OEL display device 200 only needs an OEL layer 23, which can generate a whit light source S. Thus, the times of the evaporation processes are reduced and the overall manufacturing processes are simplified. Moreover, the difficulty of precisely aligning the mask and the evaporation source is also reduced. However, the poor transmittance of the white light source S to the color filter layer 15 affects the brightness and the color saturation of the OEL display device 200. Thus, the display quality of the OEL display device cannot be improved.

### SUMMARY

In accordance with the foregoing and other aspects of the present invention, an organic electroluminescent (OEL) display device with color level enhancement is provided. The OEL display device comprises a plurality of pixels on a substrate. Each of the pixels comprises a first color filter layer, a first electrode, a first OEL layer, a second OEL layer and a second electrode. The first color filter layer is disposed on the substrate, comprising at least a first photo resist, at least a second photo resist, at least a third photo resist and at least a fourth photo resist, wherein the fourth photo resist is a colorless transparent region. The first electrode is disposed on the first color filter layer. The first OEL layer is disposed on the first electrode on the vertically extended position of the first photo resist and the fourth photo resist. The second OEL layer is disposed on the first electrode on the vertically extended position of the second photo resist, the third photo resist and the fourth photo resist. The second electrode is disposed on the first OEL layer and the second OEL layer. In an embodiment, the first OEL layer further extends to the vertically extended position of the second photo resist, the third photo resist or both.

In accordance with the foregoing and other aspects of the present invention, an organic electroluminescent (OEL) display device with color level enhancement is provided. The organic electroluminescent (OEL) display device comprises a plurality of pixels on a substrate. Each of the pixels comprises a first electrode, a first OEL layer, a second OEL layer, a second electrode, an assembly cover plate and a first color filter layer. The first electrode is disposed on the substrate. The first OEL layer and the second OEL layer are disposed on the first electrode. The second electrode is disposed on the first OEL layer and the second OEL layer. The assembly cover plate is disposed on the second electrode. The first color filter layer is disposed on the bottom of the assembly cover plate, comprising at least a first photo resist, at least a second photo resist, at least a third photo resist and at least a fourth photo resist. The fourth photo resist is a colorless transparent region. The first OEL layer is disposed below the vertically extended position of the first photo resist and the fourth photo resist. The second OEL layer is disposed below the vertically extended position of the second photo resist, the third photo resist and the fourth photo resist.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of a traditional OEL display device;

FIG. 2-5 are cross-sectional views of OEL display devices according to the first, the second, the third and the fourth embodiments; and

FIG. 6 is a top view of an OEL display device according to the fifth embodiment.

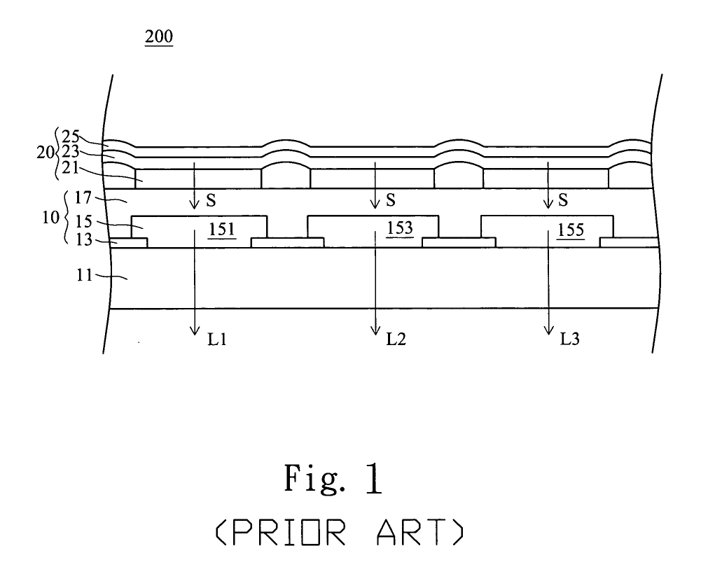

### DETAILED DESCRIPTION

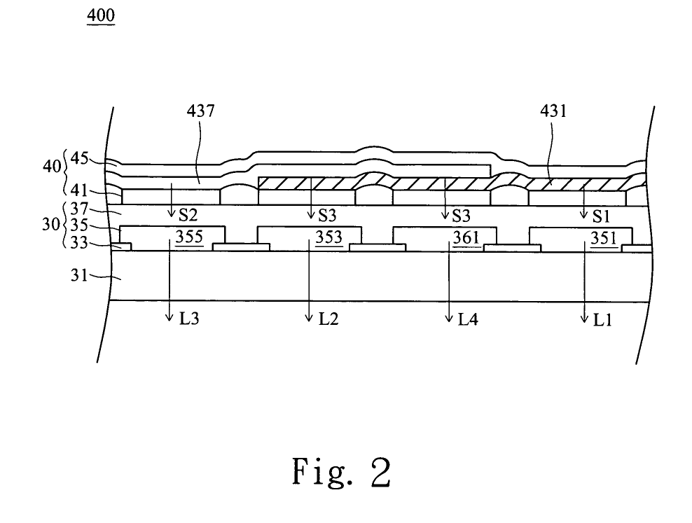

FIG. 2 is a cross-sectional view of an organic electroluminescent (OEL) display device according to the first embodiment. In FIG. 2, the OEL display device comprises mainly an OEL device 40 disposed on a color filter 30. The OEL display device comprises a plurality of pixels. In order to clearly explain the concepts of the invention, the embodiments of the invention will be explained based on a single pixel. In the pixel 400 of the OEL display device, the OEL device 40 comprises a first electrode 41, a first OEL layer 431, a second OEL layer 437 and a second electrode 45.

The color filter 30 is disposed on a substrate 31. The color filter 30 comprises at least a black matrix 33 on the substrate 31. The color filter 30 also comprises a first color filter layer 35, which can filter light. The first color filter layer 35 is disposed on the black matrix 33 and the substrate 31 where no black matrix 33 is formed thereon. The first color filter layer 35 comprises a first photo resist 351, a second photo resist 353, a third photo resist 355 and a fourth photo resist 361. The fourth photo resist 361 is a colorless transparent region. A planarization barrier element 37 covers the black matrix 33 and the first color filter layer 35. The planarization barrier element 37 can be an over coat layer, a barrier layer or both.

The first electrode 41 of the OEL device 40 is disposed on the planarization barrier element 37 of the color filter 30. The first OEL layer 431, the second OEL layer 437 and the second electrode 45 are sequentially disposed on the first electrode 41. When a working current is conducted between the first electrode 41 and the second electrode 45, the first OEL layer 431 generates a first light source S1 and the second OEL layer 437 generates a second light source S2. The color of the first light source S1 is complementary to the color of the second light source S2.

The first OEL layer 431 is disposed on the first electrode 41 on the vertically extended position of the first photo resist 351, the second photo resist 353 and the fourth photo resist 361 of the color filter 30. The second OEL layer 437 is disposed on the first electrode 41 and the first OEL layer 431 on the vertically extended position of the third photo resist 355, the second photo resist 353 and the fourth photo resist 361 of the color filter 30.

A first light source S1 is generated from the first OEL layer 431, filtered by the first photo resist 351 and then converted to a first color light L1. A second light source S2 is generated from the second OEL layer 437, filtered by the third photo resist 355 and then converted to a third color light L3. On the vertically extended position of the second photo resist 353 and the fourth photo resist 361, the overlap between the first OEL layer 431 and the second OEL layer 437 generates a third light source S3. Because the color of the first light source S1 is complementary to the color of the second light source S2, the color of the third light source S3 is white. The third light source S3 is filtered by the second photo resist 353 and converted to a second color light L2. Because the fourth photo resist 361 is a colorless transparent photo resist, the third light source S3 will directly pass through the fourth photo resist 361 without changing its color.

In an embodiment, the first light source S1 generated from the first OEL layer 431 is a blue light source. The color of the second light source S2 generated from the second OEL layer 437 is complementary to the color of the first light source S1. The second light source S2 is an orange light source or a yellow light source, correspondingly. The third light source S3 generated from the overlap between first OEL layer 431 and the second OEL layer 437 is a white light source. Because the first photo resist 351 is a blue photo resist, the first light source S1 with blue color will be filtered by the first photo resist 351 to be converted to a first color light L1 which is blue. Because the third photo resist 355 is a red photo resist, the second light source S2 with orange color will be filtered by the third photo resist 355 and be converted to a third color light L3 which is red. Because the second photo resist 353 is a green photo resist, the third light source S3 with white color will be filtered by the second photo resist 353 to be converted to a second color light L2 which is green. Because the fourth photo resist 361 is a colorless transparent photo resist, the third light source S3 with white color will directly pass through the fourth photo resist 361 to form a fourth color light L4 which is white. The position of the second photo resist 353 and the position of the fourth photo resist 361 can be swapped to achieve the same color filtering effect.

In another embodiment, the first light source S1 generated from the first OEL layer 431 is a red light source or a green light source. The color of the second light source S2 generated from the second OEL layer 437 is complementary to the color of the first light source S1. The second light source S2 is a cyan light source or a purple light source, correspondingly. With different color selection of the first light source S1 and the second light source S2, the positions of the first photo resist 351, the second photo resist 353, the third photo resist 355 and the fourth photo resist 361 can be changed to achieve the object of full color display.

The position sequence of the first OEL layer 431 and the second OEL layer 437 can be swapped. For example, the second OEL layer 437 is disposed on the first electrode 41 on the vertically extended position of the second photo resist 353, the third photo resist 355 and the fourth photo resist 361. The first OEL layer 431 is disposed on the first electrode 41 and the second OEL layer 437 on the vertically extended position of the first photo resist 351, the second photo resist 353 and the fourth photo resist 361 of the color filter 30.

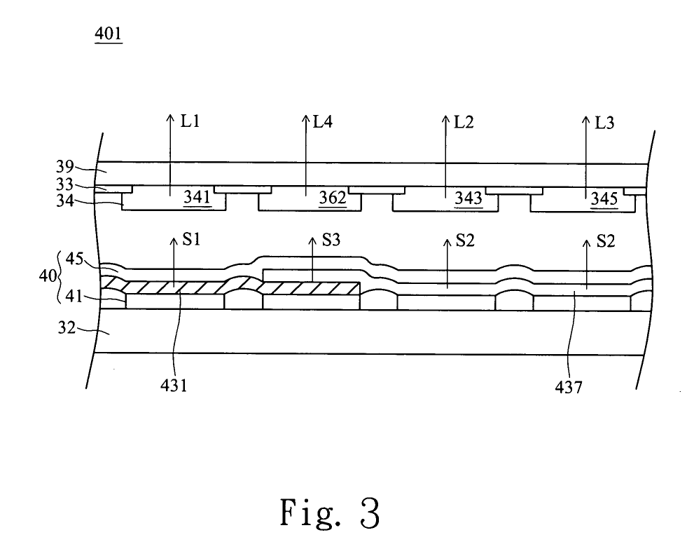

FIG. 3 is a cross-sectional view of an OEL display device according to the second embodiment. In the pixel 401 of the OEL display device, an OEL device 40 comprises a first electrode 41, a first OEL layer 431, a second OEL layer 437 and a second electrode 45. The OEL device 40 is disposed on a substrate 32. An assembly cover plate 39 is disposed on the OEL device 40 to protect it. At least a black matrix 33 is disposed on the bottom of the assembly cover plate 39. The second color filter layer 34 is disposed on the black matrix 33 and the bottom of the assembly cover plate 39 where no black matrix 33 is formed thereon. The second color filter layer 34 comprises a fifth photo resist 341, a sixth photo resist 343, a seventh photo resist 345 and an eighth photo resist 362.

The first electrode 41 is disposed on the substrate 32 and under the second color filter layer 34. The first OEL layer 431 is disposed on the first electrode 41 under the vertically extended position of the fifth photo resist 341 and the eighth photo resist 362. The second OEL layer 437 is disposed on the first electrode 41 and the first OEL layer 431 under the vertically extended position of the seventh photo resist 345, the sixth photo resist 343 and the eighth photo resist 362. The second electrode 45 is disposed on the first OEL layer 431 and the second OEL layer 437. The second electrode 45 can be made from a transparent and conductive material. Therefore, the first light source S1 from the first OEL layer 431, the second light source S2 from the second OEL layer 437 and the third light source S3 from the overlap between the first OEL layer 431 and the second OEL layer 437 can sequentially pass through the second electrode 45 and the second color filter layer 34 to obtain top-emission of the OEL display device.

The color filter 30 of FIG. 2 can be disposed between the substrate 32 and the first electrode 41. Therefore, the first light source S1, the second light source S2 and the third light source S3 can simultaneously pass through both the assembly cover plate 39 and the color filter 30 to obtain double-emission of the OEL display device.

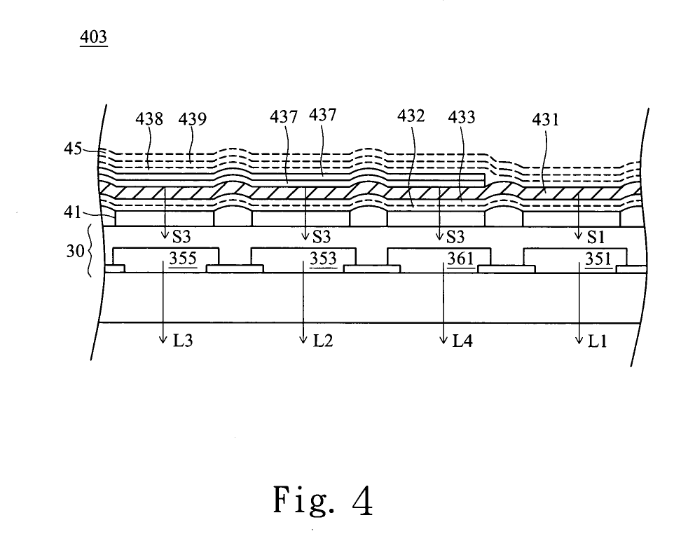

FIG. 4 is a cross-sectional view of an OEL display device according to the third embodiment. In the pixel 403 of the OEL display device, an OEL device comprises a first electrode 41, a first OEL layer 431, a second OEL layer 437 and a second electrode 45. The first OEL layer 431 is disposed on the vertically extended position of the first photo resist 351, the second photo resist 353, the third photo resist 355 and the fourth photo resist 361. The second OEL layer 437 is disposed on the vertically extended position of the third photo resist 355, the second photo resist 353 and the fourth photo resist 361.

The OEL device comprises a hole injection layer 432 (HIL), a hole transport layer 433 (HTL), a first OEL layer, a second OEL layer, an electron transport layer 438 (ETL) and an electron injection layer 439 (EIL).

In an embodiment, a HIL 432 and a HTL 433 are sequentially disposed on the first electrode 41. A first OEL layer 431 is disposed on the HTL 433. A second OEL layer 437 is disposed on the first OEL layer 431. An ETL 438, an EIL 439 and a second electrode 45 are sequentially disposed on the first OEL layer 431 and the second OEL layer 437.

Moreover, the first OEL layer 431 and the second OEL layer 437 can be single layer or multi-layer. In FIG. 4, the first OEL layer 431 is single layer. The second OEL layer 437 is double-layer.

Moreover, the first OEL layer 431 and the second OEL layer 437 can be a doped layer, which comprises at least a host emitter doped with at least a dopant, to generate a first light source S1 and a second light source S2.

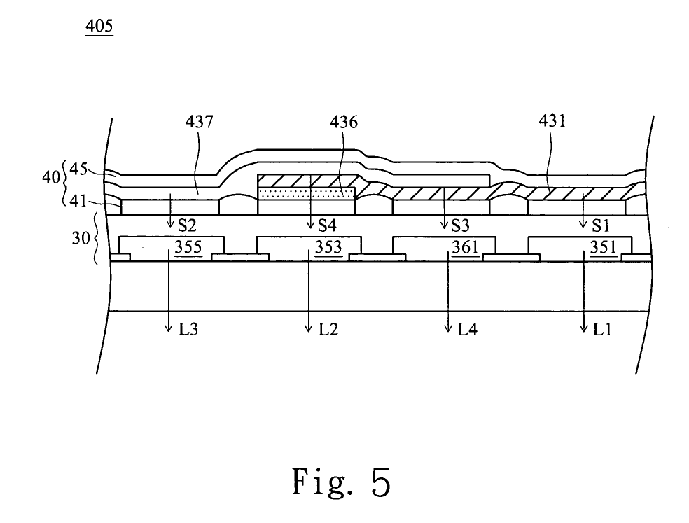

FIG. 5 is a cross-sectional view of an OEL display device according to the fourth embodiment. In the pixel 405 of the OEL display device, an OEL device 40 comprises a first electrode 41, a first OEL layer 431, a second OEL layer 437 and a second electrode 45. The OEL device 40 disposed on a color filter 30. The major difference between the fourth embodiment and the first embodiment of FIG. 2 is a third OEL layer 436.

The third OEL layer 436 is used to enhance the display brightness of some color light source of the OEL display device. In this embodiment, the display light source of the OEL display device is green light source-deficient. The third OEL layer 436 is disposed on the first electrode 41 on the vertically extended position of the second photo resist 353, which is a green photo resist, and the color of the fourth light source S4 generated from the first OEL layer 431, the second OEL layer 437 and the third OEL layer is also green color. Therefore, the display brightness of green color light source of the OEL display device is enhanced.

Based on the color of the light source that the OEL display device is deficient in, the color of the fourth light source S4 can change, and the position of the third OEL layer 436 can change. The third OEL layer 436 can be disposed on the first electrode 41 on the vertically extended position of the first photo resist 351 or the third photo resist 355.

The OEL display device can be designed to be an active matrix OEL display device. In an embodiment, the active matrix OEL display device comprises a plurality of thin film transistors (TFTs) electrically connected with the first electrode 41. The arrangement of the TFTs in the active matrix OEL display can be color filter on array (COA) or array on color filter (array on color filter).

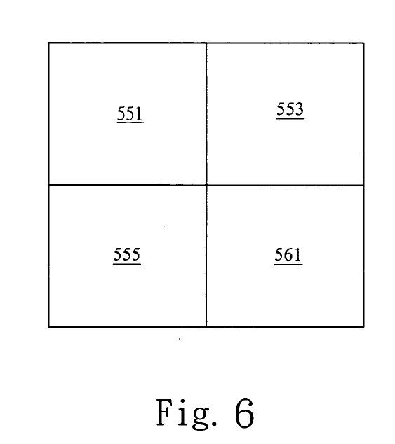

FIG. 6 is a top view of an OEL display device according to the fifth embodiment. In FIG. 6, the first photo resist 551, the second photo resist 553, the third photo resist 555 and the fourth photo resist 561 of the color filter 50 of an OEL display device can be arranged as a matrix, instead of a line, to well mix color lights. When the position arrangement of each photo resist is changed, the position arrangement of the first OEL layer and the second OEL layer also need to be changed correspondingly.

Accordingly, the present invention has the following advantages.

(1) The times of the evaporation processes in the manufacturing processes for the OEL display device of the invention are reduced. Therefore, the overall manufacturing processes are simplified and thus the production cost is reduced. Moreover, the difficulty of precisely aligning the mask and the evaporation source is reduced. Therefore, the product failure rate is also reduced.

(2) In the OEL display device, the color level and the color saturation of the OEL display device can be enhanced by mixing the first color light, the second light, the third color light and a white light.

(3) Because the transmittance of the light source of the OEL display device to the color filter layer is high, the brightness and the color saturation of the OEL display device can be increased. Therefore, the color level and the display quality of the OEL display device can also be efficiently enhanced.

The embodiments of the present invention described above should not be regarded as limitations to the present invention. It will be apparent to those skilled in the art that various modifications and variations can be made to the present invention without departing from the scope or spirit of the invention. The scope of the present invention is as defined in the appended claims.

What is claimed is:

1. An organic electroluminescent (OEL) display device with color level enhancement, comprising:
a plurality of pixels on a substrate, wherein each of the pixels comprising:
a first color filter layer disposed on the substrate, comprising a first photo resist, a second photo resist, a third photo resist and a fourth photo resist, wherein the fourth photo resist is a colorless transparent region;
a first electrode disposed on the first color filter layer;
a first OEL layer disposed on the first electrode on the vertically extended position of the first photo resist and the fourth photo resist;
a second OEL layer disposed on the first electrode on the vertically extended position of the second photo resist, the third photo resist and the fourth photo resist; and
a second electrode disposed on the first OEL layer and the second OEL layer.

2. The OEL display device of claim 1, further comprising a plurality of TFTs electrically connected with the first electrode.

3. The OEL display device of claim 1, further comprising:
an assembly cover plate disposed on the second electrode; and
a second color filter layer disposed on the bottom of the assembly cover plate, comprising a fifth photo resist, a sixth photo resist, a seventh photo resist and an eighth photo resist on the corresponding position of the first, second, third, and fourth photo resist, respectively, wherein the eighth photo resist is a colorless transparent region.

4. The OEL display device of claim 3, further comprising a plurality of TFTs electrically connected with the first electrode.

5. The OEL display device of claim 1, wherein the first OEL layer further extends to the vertically extended position of the second photo resist, the third photo resist or both.

6. The OEL display device of claim 5, further comprising a plurality of TFTs electrically connected with the first electrode.

7. The OEL display device of claim 5, further comprising:
an assembly cover plate disposed on the second electrode; and
a second color filter layer disposed on the bottom of the assembly cover plate, comprising a fifth photo resist, a sixth photo resist, a seventh photo resist and an eighth photo resist on the corresponding position of the first, second, third, and fourth photo resist, respectively, wherein the eighth photo resist is a colorless transparent region.

8. The OEL display device of claim 7, further comprising a plurality of TFTs electrically connected with the first electrode.

9. The OEL display device of claim 5, further comprises a third OEL layer disposed on the first electrode on the first photo resist, the second photo resist or the third photo resist.

10. The OEL display device of claim 9, further comprising a plurality of TFTs electrically connected with the first electrode.

11. The OEL display device of claim 9, further comprising:
an assembly cover plate disposed on the second electrode; and
a second color filter layer disposed on the bottom of the assembly cover plate, comprising a fifth photo resist, a sixth photo resist, a seventh photo resist and an eighth photo resist on the corresponding position of the first, second, third, and fourth photo resist, respectively, wherein the eighth photo resist is a colorless transparent region.

12. The OEL display device of claim 11, further comprising a plurality of TFTs electrically connected with the first electrode.

13. The OEL display device of claim 1, wherein the first OEL layer is a single layer or a multi-layer or a doped layer, and the second OEL layer is a single layer, a multi-layer or a doped layer.

14. The OEL display device of claim 1, wherein the OEL device further comprises a hole injection layer (HIL), a hole transport layer (HTL), an electron transport layer (ETL) and an electron injection layer (EIL), and the HIL, the HTL, the first OEL layer, the second OEL layer, the ETL and the EIL are sequentially disposed between the first electrode and the second electrode.

15. The OEL display device of claim 1, wherein a color of the light generated from the first OEL layer is complementary to a color of the light generated from the second OEL layer.

16. An organic electroluminescent (OEL) display device with color level enhancement, comprising:
a plurality of pixels on a substrate, wherein each of the pixels comprising:
a first electrode disposed on the substrate;
a first OEL layer and a second OEL layer disposed on the first electrode;
a second electrode disposed on the first OEL layer and the second OEL layer;
an assembly cover plate disposed on the second electrode; and
a first color filter layer disposed on the bottom of the assembly cover plate, comprising at least a first photo resist, at least a second photo resist, at least a third photo resist and at least a fourth photo resist, wherein the fourth photo resist is a colorless transparent region, the first OEL layer is disposed below the vertically extended position of the first photo resist and the fourth photo resist, and the second OEL layer is disposed below the vertically extended position of the second photo resist, the third photo resist and the fourth photo resist.

17. The OEL display device of claim 16, wherein the first OEL layer further extends to the vertically extended position of the second photo resist, the third photo resist or both.

18. The OEL display device of claim 16, further comprising a plurality of TFTs electrically connected with the first electrode.

19. The OEL display device of claim 16, wherein the first OEL layer is a single layer, a multi-layer or a doped layer, and the second OEL layer is a single layer, a multi-layer or a doped layer.

20. The OEL display device of claim 16, wherein the OEL device further comprises a hole injection layer (HIL), a hole transport layer (HTL), an electron transport layer (ETL) and an electron injection layer (EIL), and the HIL, the HTL, the first OEL layer, the second OEL layer, the ETL and the EIL are sequentially disposed between the first electrode and the second electrode.

21. The OEL display device of claim 16, further comprises a third OEL layer disposed on the first electrode below the first photo resist, the second photo resist or the third photo resist.

22. The OEL display device of claim 16, wherein a color of the light generated from the first OEL layer is complementary to a color of the light generated from the second OEL layer.
